(19) United States
(12) Patent Application Publication
(10) Pub. No.: US 2025/0329527 A1
(43) Pub. Date: Oct. 23, 2025

(54) MICROWAVE APPARATUS FOR DUAL MODE OPERATION AND METHODS OF USE

(71) Applicant: Applied Materials, Inc., Santa Clara, CA (US)

(72) Inventors: Bencherki Mebarki, Santa Clara, CA (US); Yoon Ah Shin, Santa Clara, CA (US); Joung Joo Lee, San Jose, CA (US)

(73) Assignee: Applied Materials, Inc., Santa Clara, CA (US)

(21) Appl. No.: 18/637,574

(22) Filed: Apr. 17, 2024

(51) Int. Cl. H01L 21/02; B08B 5/00; B08B 7/00; H01J 37/32

(52) U.S. Cl. CPC H01L 21/0206; B08B 5/00; B08B 7/0035; H01J 37/32201; H01L 21/02068; H01J 2237/335

(57) ABSTRACT

Semiconductor manufacturing processing chambers with dual mode microwave sources and methods of use are described. The methods comprise removing carbon residue from a substrate surface by exposing the substrate surface located adjacent to a first side of a permeable barrier to a microwave plasma generated by a microwave source located adjacent to a second side of the permeable barrier. Metal oxides are reduced from a substrate surface by exposing the substrate surface to microwave radiation from the microwave source through the permeable barrier without generating a plasma.

### TECHNICAL FIELD

Embodiments of the disclosure are directed to semiconductor manufacturing processing chamber with microwave plasma sources. In particular, embodiments of the disclosure are directed to semiconductor manufacturing processing chambers with microwave plasma sources with dual mode operation and processing methods using dual mode microwave sources.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, tolerances for individual layer damage decreases. Microwave plasma is an efficient way of reducing metal oxides and chemical residues but damages low-k dielectric materials. Microwave radiation can be used in non-plasma processes and is effective to reduce metal oxides while being gentle on low-k dielectric films but is weak at removing carbon residue from films.

Accordingly, there is a need in the art for improved methods for reducing meal oxides and carbon residue without damaging low-k dielectric films.

### SUMMARY

One or more embodiments of the disclosure are directed to semiconductor manufacturing processing methods including: removing carbon residue from a substrate surface by exposing the substrate surface located adjacent to a first side of a permeable barrier to a microwave plasma generated by a microwave source located adjacent to a second side of the permeable barrier; and reducing metal oxides from a substrate surface by exposing the substrate surface to microwave radiation from the microwave source through the permeable barrier without generating a plasma.

Additional embodiments of the disclosure are directed to semiconductor manufacturing processing methods including: removing carbon residue from a substrate surface including a metal surface and a low-k dielectric surface by exposing the substrate surface located adjacent to a first side of a permeable barrier to hydrogen radicals from a microwave plasma generated by a microwave source, the microwave plasma generated on a second side of the permeable barrier; and reducing metal oxides from a substrate surface by exposing the substrate surface to microwave radiation from the microwave source through the permeable barrier without generating a plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic representation of a processing tool comprising a modular high-frequency emission source with a source array that comprises a plurality of applicators according to one or more embodiments of the disclosure;

FIG. 2 illustrates a block diagram of a modular high-frequency emission module according to one or more embodiments of the disclosure;

FIG. 3 illustrates a schematic exploded perspective view of an assembly according to one or more embodiments of the disclosure;

FIG. 4 illustrates a schematic perspective view of a source array with dielectric resonators in cavities in a dielectric plate according to one or more embodiments;

FIG. 5 illustrates a cross-sectional view of a processing tool according to one or more embodiments;

FIG. 6 shows a cross-sectional schematic view of a processing chamber in accordance with one or more embodiment of the disclosure;

FIG. 7 shows a cross-sectional schematic view of a substrate with a surface feature for use with one or more embodiments of the disclosure; and

FIG. 8 shows a cross-sectional schematic view of a substrate during a method according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

PreClean, also known as pre-cleaning, refers to a process in the semiconductor industry that is performed before the actual fabrication of integrated circuits (ICs). Pre-cleaning involves the removal of various contaminants from the surface of the silicon wafer or other substrate materials. PreClean may be an important step in semiconductor manufacturing, depending on the particular process conditions and methods, as pre-cleaning helps to ensure the quality and reliability of the final ICs. The PreClean process typically involves several cleaning steps, including chemical and/or physical methods, to remove particles, organic residues, metal ions, and other impurities from the wafer surface. The specific methods used in PreClean can vary depending on the level of cleanliness intended for subsequent fabrication processes. Some common techniques include, but are not limited to, solvent cleaning, acid cleaning, plasma cleaning, and ultrasonic cleaning.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

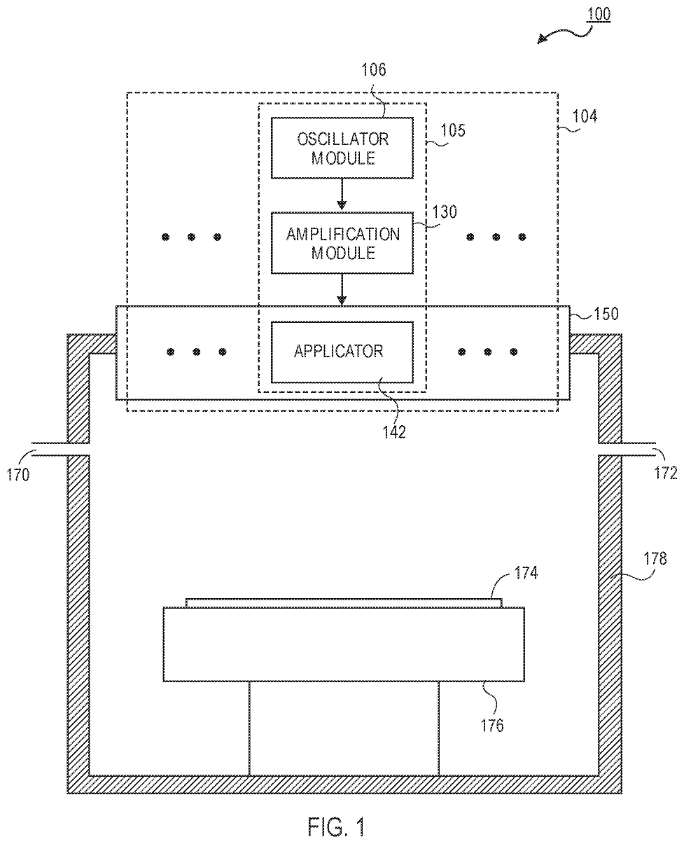

FIG. 1 illustrates a schematic representation of a processing tool 100. In some embodiments, the processing tool 100 may be a processing tool suitable for any type of processing operation that utilizes a plasma. For example, the processing tool 100 may be a processing tool used for plasma enhanced chemical vapor deposition (PECVD), plasma enhanced atomic layer deposition (PEALD), etch and selective removal processes, and plasma cleaning.

The processing tool 100 includes a semiconductor processing chamber 178. In one or more embodiments, the semiconductor processing chamber 178 is a vacuum chamber. A vacuum chamber may include a pump (not shown) for removing gases from the chamber to provide the desired vacuum. Additional embodiments may include a semiconductor processing chamber 178 that includes one or more gas lines 170 for providing processing gasses into the semiconductor processing chamber 178 and exhaust lines 172 for removing byproducts from the semiconductor processing chamber 178. While not shown, it is to be appreciated that gas may also be injected into the semiconductor processing chamber 178 through a source array 150 (e.g., as a showerhead) for evenly distributing the processing gases over a substrate 174.

In one or more embodiments, the substrate 174 is supported on a chuck 176. For example, the chuck 176 may be any suitable chuck, such as an electrostatic chuck. The chuck 176 may also include cooling lines and/or a heater to provide temperature control to the substrate 174 during processing. Due to the modular configuration of the high-frequency emission modules described herein, embodiments allow for the processing tool 100 to accommodate any sized substrate 174. For example, the substrate 174 may be a semiconductor wafer (e.g., 200 mm, 300 mm, 450 mm, or larger). Alter-native embodiments also include substrates 174 other than semiconductor wafers. For example, embodiments may include a processing tool 100 configured for processing glass substrates, (e.g., for display technologies).

In one or more embodiments, the processing tool 100 includes a modular high-frequency emission source 104. The modular high-frequency emission source 104 includes an array of high-frequency emission modules 105. In one or more embodiments, each high-frequency emission module 105 independently includes an oscillator module 106, an amplification module 130, and an applicator 142. As shown, the applicators 142 are schematically shown as being integrated into the source array 150. The skilled artisan will appreciate that the disclosure is not limited to the applicators 142 being integrated into the source array 150.

In one or more embodiments, the oscillator module 106 and the amplification module 130 may comprise electrical components that are solid state electrical components. In one or more embodiments, each of the plurality of oscillator modules 106 are independently communicatively coupled to different amplification modules 130. In some embodiments there may be a 1:1 ratio between oscillator modules 106 and amplification modules 130. For example, each oscillator module 106 may be electrically coupled to a single amplification module 130.

In one or more embodiments, each oscillator module 106 independently generates high-frequency electromagnetic radiation that is transmitted to the amplification module 130. After processing by the amplification module 130, the electromagnetic radiation is transmitted to the applicator 142. In one or more embodiments, the applicators 142 each emit electromagnetic radiation into the semiconductor processing chamber 178.

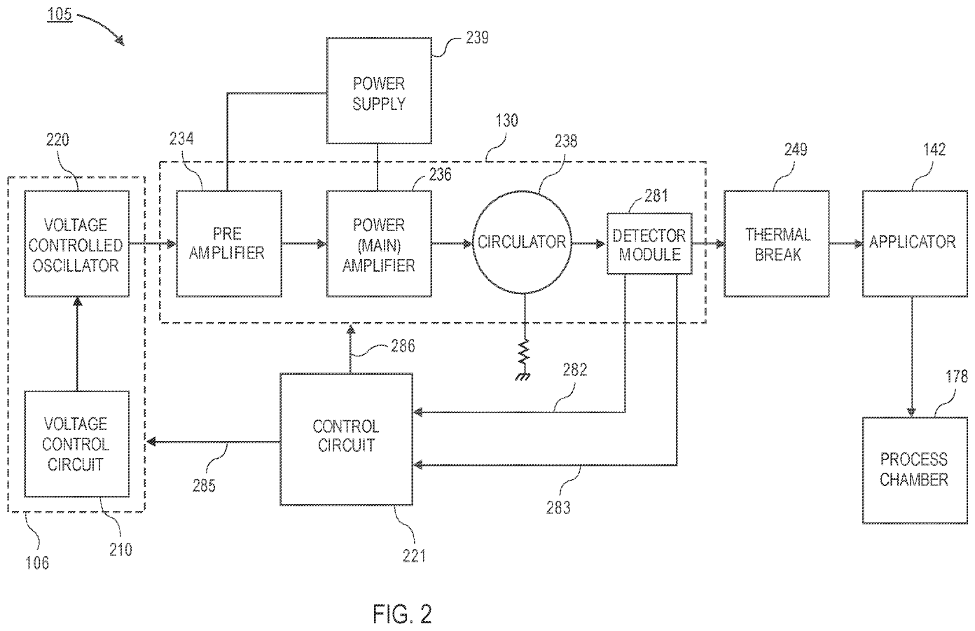

FIG. 2 illustrates a block diagram of a high-frequency emission module 105. In one or more embodiments, the high-frequency emission module 105 comprises an oscillator module 106. The oscillator module 106 may include a voltage control circuit 210 for providing an input voltage to a voltage-controlled oscillator 220 in order to produce high-frequency electromagnetic radiation at a desired frequency. One or more embodiments include an input voltage in a range of from 1 V to 10V of DC. In one or more embodiments, the voltage-controlled oscillator 220 is an electronic oscillator whose oscillation frequency is controlled by the input voltage. According to one or more embodiments, the input voltage from the voltage control circuit 210 results in the voltage-controlled oscillator 220 oscillating at a desired frequency. In some embodiments, the high-frequency electromagnetic radiation has a frequency in a range of from about 0.1 MHz to about 30 MHz. In some embodiments, the high-frequency electromagnetic radiation has a frequency in a range of from about 30 MHz to about 300 MHz. In some embodiments, the high-frequency electro-magnetic radiation has a frequency in a range of from about 300 MHz to about 1 GHz. In some embodiments, the high-frequency electromagnetic radiation has a frequency in a range of from about 1 GHz to about 300 GHz.

According to one or more embodiments, the electromagnetic radiation is transmitted from the voltage-controlled oscillator 220 to an amplification module 130. The amplification module 130 may include a driver/pre-amplifier 234, and a main power amplifier 236 that are each coupled to a power supply 239. According to one or more embodiments, the amplification module 130 may operate in a pulse mode. For example, the amplification module 130 may have a duty cycle in a range of from 1% to 99%. In specific embodiments, the amplification module 130 may have a duty cycle in a range of from 15% to 50%.

In some embodiments, the electromagnetic radiation may be transmitted to the thermal break 249 and the applicator 142 after being processed by the amplification module 130. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. The skilled artisan will appreciate that the detector module 281 may be located at one or more different locations in the system (e.g., between the circulator 238 and the thermal break 249). In some embodiments, the control circuit module 221 interprets the forward power 283 and the reflected power 282, and determines the level for the control signal 285 that is communicatively coupled to the oscillator module 106 and the level for the control signal 286 that is communicatively coupled to the amplification module 130. In some embodiments, control signal 285 adjusts the oscillator module 106 to optimize the high-frequency radiation coupled to the amplification module 130. In some embodiments, control signal 286 adjusts the amplification module 130 to optimize the output power coupled to the applicator 142 through the thermal break 249.

Accordingly, one or more embodiments allow for an increased percentage of the forward power to be coupled into the semiconductor processing chamber 178, and increases the available power. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage-controlled oscillator 220.

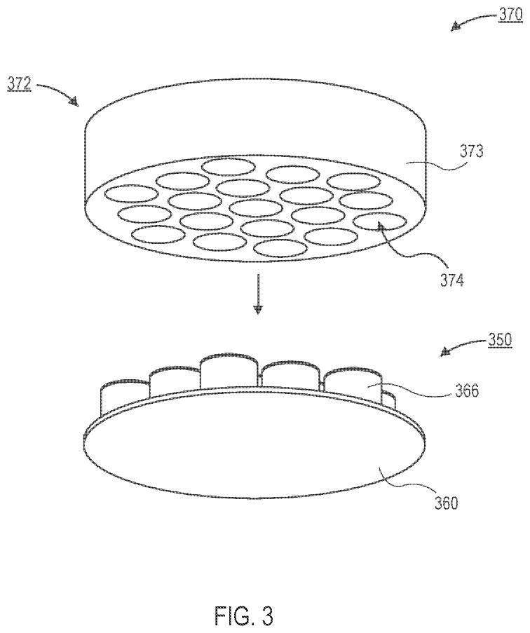

Referring now to FIG. 3, a schematic exploded perspective view of an microwave source assembly 370 is shown. The microwave source assembly 370 comprises a source array 350 and a housing 372. As indicated by the arrows, the housing 372 fits over and around the source array 350. In the illustrated embodiment, the microwave source assembly 370 is shown as having a substantially circular shape. However, the skilled artisan will appreciate that the microwave source assembly 370 may have any suitable shape such as polygonal, elliptical, wedge shaped, or the like. In some embodiments, the source array 350 comprises a dielectric plate 360 and a plurality of dielectric resonators 366 on the dielectric plate 360. In some embodiments, the dielectric plate 360 and the plurality of dielectric resonators 366 are a monolithic structure. That is, in embodiments where the dielectric plate 360 and the plurality of dielectric resonators 366 are a monolithic structure, there is no physical interface between a bottom of the dielectric resonators 366 and the dielectric plate 360. As used herein, a “physical interface” refers to a first surface of a first discrete body contacting a second surface of a second discrete body.

In other embodiments, the dielectric plate 360 and the dielectric resonators 366 are discrete components. Each of the dielectric resonators 366 are a portion of the applicator 142 used to inject high-frequency electromagnetic radiation into a processing chamber, such as the semiconductor processing chamber 178.

In some embodiments, the source array 350 comprises a dielectric material. For example, the source array 350 may be a ceramic material. In some embodiments, one suitable ceramic material that may be used for the source array 350, as an example, is aluminum oxide (Al₂O₃). In specific embodiments where the dielectric plate 360 and the plurality of dielectric resonators 366 are a monolithic structure, the monolithic structure may be fabricated from a single block of material. In other embodiments, a rough shape of the source array 350 may be formed with a molding process, and subsequently machined to provide the final structure with the desired dimensions. For example, green state machining and firing may be used to provide the desired shape of the source array 350. In the illustrated embodiment, the dielectric resonators 366 are shown as having a circular cross-section (when viewed along a plane parallel to the dielectric plate 360). However, the skilled artisan will appreciate that the dielectric resonators 366 may comprise many different cross-sections. For example, the cross-section of the dielectric resonators 366 may have any shape that is centrally symmetric.

In one or more embodiments, the housing 372 comprises a conductive body 373. The conductive body may include any suitable conductive material. For example, the conductive body 373 may be aluminum or the like. The housing comprises a plurality of openings 374. The openings 374 may pass entirely through a thickness of the conductive body 373. The openings 374 may be sized to receive the dielectric resonators 366. For example, as the housing 372 is displaced towards the source array 350 (as indicated by the arrow) the dielectric resonators 366 will be inserted into the openings 374.

In the illustrated embodiment of FIG. 3, the housing 372 is shown as a single conductive body 373. However, the skilled artisan will appreciate that the housing 372 may comprise one or more discrete conductive components. The discrete components may be individually grounded, or the discrete components may be joined mechanically or by any form of metallic bonding, to form a single electrically conductive body 373.

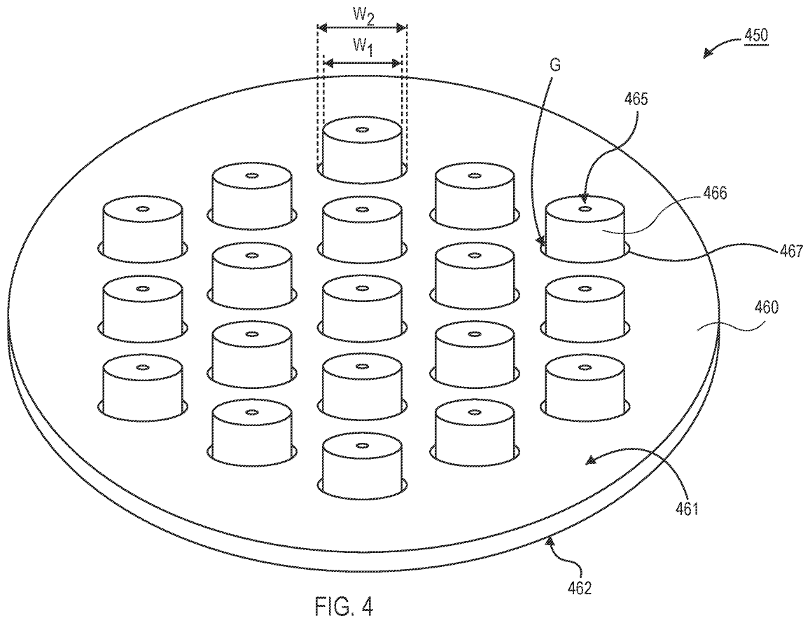

FIG. 4 illustrates a schematic perspective view of a source array 450. In one or more embodiments, the source array 450 comprises the same components and features as the source array 350 shown in FIG. 3. Accordingly, unless provided otherwise, the source array 350 and source array 450 may be described interchangeably. In one or more embodiments, the source array 150 from FIG. 1 includes the same components and features as the source array 350 and source array 450.

In FIG. 4, the source array 450 comprises a dielectric plate 460. A plurality of cavities 467 are disposed into a first surface 461 (e.g., a top surface) of the dielectric plate 460. The cavities 467 do not pass through to a second surface 462 (e.g., a bottom surface) of the dielectric plate 460. Stated differently, the cavities 467 do not pass through a thickness of the dielectric plate 460. The source array 450 may further include a plurality of dielectric resonators 466. Each of the dielectric resonators 466 may be in a different one of the cavities 467.

In embodiments where the dielectric plate 460 and the plurality of dielectric resonators 466 are a monolithic structure, the bottom of the cavity 467 is entirely outside a perimeter defined by the sidewalls of the dielectric resonators 466. In some embodiments, the cavity 467 may be referred to as a groove into the first surface 461 that surrounds the dielectric resonator 466.

The monolithic configuration results in the cavity 467 being a ring shape. Part of the cavity 467 is defined by the sidewall of the dielectric resonator 466. More particularly, an interior surface of the ring cavity 467 is defined by the sidewall of the dielectric resonator 466 and an outer surface of the ring cavity 467 is defined by a portion of the dielectric plate 460.

In some embodiments, each of the dielectric resonators 466 independently comprises a hole 465 in the axial center of the dielectric resonator 466. In one or more embodiments, the hole 465 is sized to accommodate a monopole antenna (not shown). In one or more unillustrated embodiments, the hole 465 extends down into the body of the dielectric resonator 466. In some embodiments, a bottom of the hole 465 is below (in the Z-direction) the first surface 461 of the dielectric plate 460. Stated differently, in embodiments where the bottom of the hole 465 is below (in the Z-direction) the first surface 461 of the dielectric plate 460, the bottom of the hole 465 is within the cavity 467. In some embodiments, a bottom of the hole 465 is at or above (in the Z-direction) the first surface 461 of the dielectric plate 460.

In one or more embodiments, the dielectric resonators 466 may have a first width W₁ and the cavities 467 may have a second width W₂. In some embodiments, the first width W₁ of the dielectric resonators 466 is smaller than the second width W₂ of the cavities 467. The difference in the widths provides a gap G between a sidewall of the dielectric resonators 466 and a sidewall of the cavities 467. In the illustrated embodiment of FIG. 4, each of the dielectric resonators 466 are shown as having a uniform width W₁. However, the skilled artisan will appreciate that not all dielectric resonators 466 of the source array 450 need to have the same dimensions.

In one or more unillustrated embodiments, the source array 450 includes a conductive layer disposed over the surfaces of the source array 450.

In one or more unillustrated embodiments, the source array 350, 450 includes one or more rings configured to separate the sidewall of the opening 374 in the housing 372 from the sidewall of the dielectric resonator 466. In such embodiments, the rings fill the gap G between the sidewall of the dielectric resonator 466 and the sidewall of the cavity 467 into the dielectric plate 460. That is, a portion of the ring extends below (in the Z-direction) the first surface 461 of the dielectric plate 460. The rings may be electrically coupled to the conductive body 373 and are grounded during operation of the processing tool. Accordingly, the entire length of the sidewall is covered by a grounded surface. It has been advantageously found that covering the entire length of the sidewall with a grounded surface improves the resonance characteristics of the source array 350, and provides improved coupling of the high-frequency electromagnetic radiation into the processing chamber, such as semiconductor processing chamber 178.

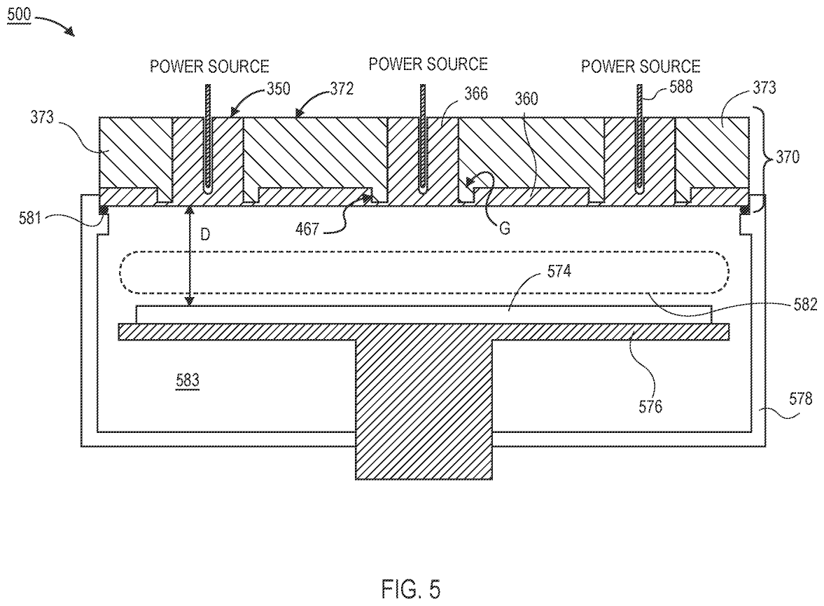

FIG. 5 illustrates a cross-sectional view of a processing tool 500 according to one or more embodiments. In one or more embodiments, the processing tool 500 comprises a semiconductor processing chamber 578 that is sealed by an microwave source assembly 370. For example, the microwave source assembly 370 may rest against one or more o-rings 581 to provide a vacuum seal to an interior volume 583 of the semiconductor processing chamber 578. In other embodiments, the microwave source assembly 370 may interface with the semiconductor processing chamber 578. That is, the microwave source assembly 370 may be part of a lid that seals the semiconductor processing chamber 578. In some embodiments, the processing tool 500 may comprise a plurality of processing volumes (which may be fluidically coupled together), with each processing volume having a different microwave source assembly 370.

In some embodiments, a chuck 576 or the like may support a workpiece 574 (e.g., wafer, substrate, etc.). In one or more embodiments, the microwave source assembly 370 is spaced a distance D from the workpiece 574. The distance D may be any suitable distance. In some embodiments, the chamber interior volume 583 may be suitable for striking a plasma 582. That is, the semiconductor processing chamber 578 may be a vacuum chamber.

In one or more embodiments, the microwave source assembly 370 comprises the source array 350 and the housing 372. As stated elsewhere herein, unless provided otherwise, the source array 350 and source array 450 may be described interchangeably.

In some embodiments, monopole antennas 588 may extend into holes 365 in the dielectric resonators 366. The monopole antennas 588 are each electrically coupled to power sources (e.g., high-frequency emission modules 105).

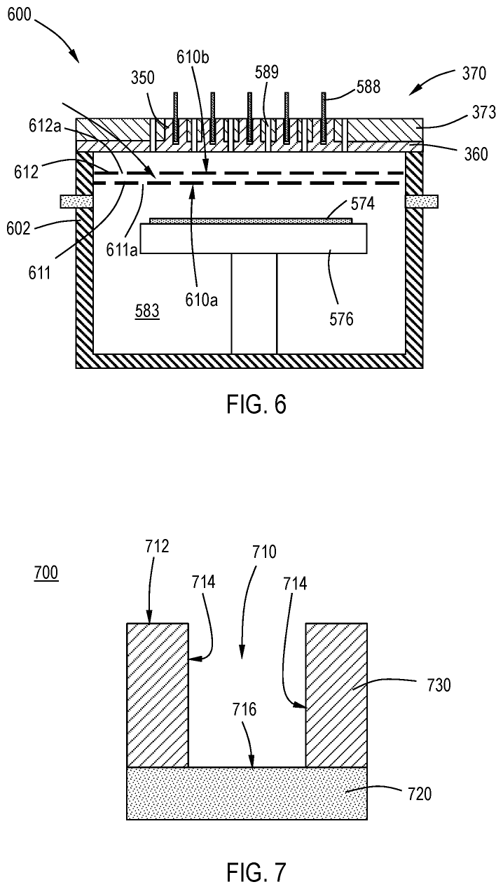

FIG. 6 illustrates an embodiment of a processing chamber 600 using the numbering system of FIG. 5. The embodiment of FIG. 6 includes a permeable barrier 610 between the dielectric plate 360 and the workpiece 574. The permeable barrier 610 of some embodiments comprises a plurality of plates 611, 612. The permeable barrier 610 of some embodiments comprises a plurality of plates 611, 612 with openings 611a, 612a therethrough. In some embodiments, the openings 611a, 612a are slit-shaped openings.

In some embodiments, the permeable barrier 610 acts as an ion filter to remove ions from the plasma generated at the dielectric plate 360, leaving substantially only radicals. In some embodiments, the permeable barrier 610 filters ions from the microwave plasma while removing carbon residue from the substrate surface.

In some embodiments, the openings 611a, 612a in the plurality of plates 611, 612 are offset to prevent ions from moving in a straight path between the plasma generated at the dielectric plate 360 and the workpiece 574. Stated differently, in some embodiments, the openings 611a, 612a through the plurality of plates are staggered slits configured so that openings in one plate are not aligned with openings in an adjacent plate.

While the embodiment illustrated in the Figures has two plates 611, 612, the skilled artisan will recognize that there can be more than two adjacent plates. For example, in some embodiments, there are three, four or five plates positioned adjacent to each other. Each plate of some embodiments is spaced a distance from the adjacent plate(s) to allow a gas to pass through the permeable barrier 610.

The permeable barrier 610 can be made of any suitable material. In some embodiments, the permeable barrier 610 comprises one or more of quartz, ceramic, a dielectric material or a metal.

FIG. 7 illustrates a schematic cross-sectional view of a substrate 700 including at least one feature 710. The feature 710 comprises a gap defined by a top surface 712, two opposed sidewalls 714, and a bottom surface 716. The two opposed sidewalls 714 may comprise any suitable material.

The feature 710 can be formed in a single material so that the sidewalls 714 and bottom surface 716 have the same composition. In the illustrated embodiments, the feature 710 is formed at the junction of different materials. For example, top surface 712 and sidewalls 714 are formed by a first material (e.g., a dielectric material 730) and the bottom surface 716 is formed by a second material (e.g., a conductive material 720). In one or more embodiments, the two opposed sidewalls 714 comprise a dielectric material 730, e.g., a low-k dielectric material such as, but not limited to, silicon oxide (SiOₓ), silicon sub-oxides, silicon nitride (SiₓN_{y}), silicon oxynitride (SiOₓN_{y}), tantalum nitride (TaN), dielectrics comprising silicon, carbon, oxygen and hydrogen atoms (SiCₓO_{y}H_{z}), and porous dielectrics. In some embodiments, the bottom surface 716 may comprise a conductive material 720, e.g., a metal. Suitable conductive materials 720 include, but are not limited to, tungsten (W), molybdenum (Mo), ruthenium (Ru), cobalt (Co), copper (Cu), zirconium (Zr), aluminum (Al) and hafnium (Hf). In some embodiments, the sidewalls 714 are formed in a conductive material and the bottom surface 716 is a dielectric material.

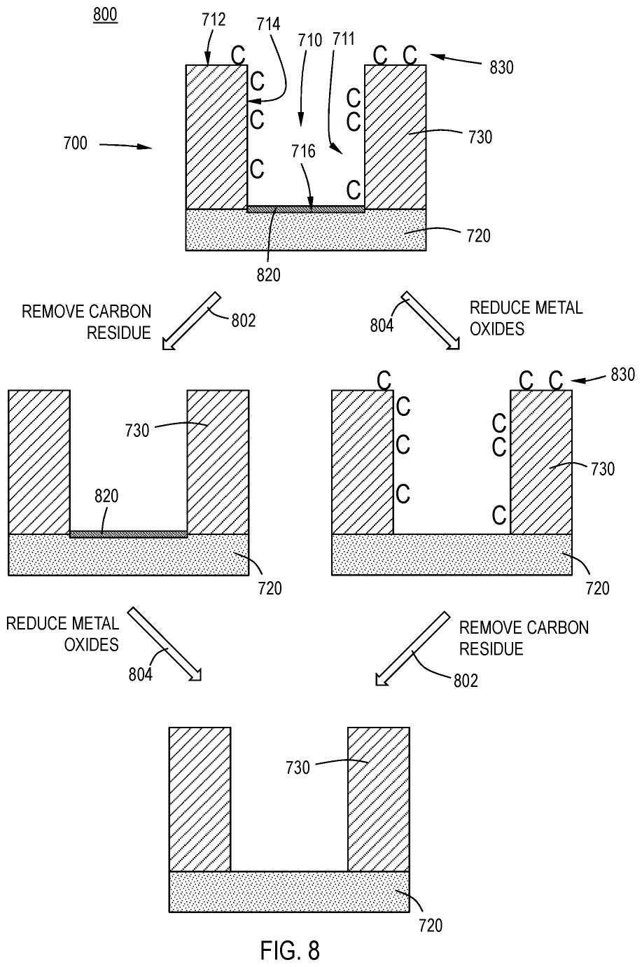

In FIGS. 7 and 8, the substrate 700 is shown having a single feature 710. However, the skilled artisan will recognize that this is merely for illustrative purposes and that the substrate 700 can include more than one feature 710. The shape of the feature 710 can be any suitable shape including, but not limited to, trenches and vias (i.e., cylindrical holes formed in a layer), as described herein.

The feature 710 has a depth measured from the top surface 712 to the bottom surface 716 and a width between the two opposed sidewalls 714. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In one or more embodiments, the aspect ratio of the trench 51 described herein is greater than or equal to about 1:1, 2:1, 5:1, 10:1, 15:1, 20:1, 25:1, 30:1, 35:1, or 40:1.

FIG. 8 illustrates a semiconductor manufacturing processing method 800 according to one or more embodiments of the disclosure. The method 800 starts with a substrate 700 with surface feature 710 comprising a first material and a second material. In the illustrated embodiments, the first material comprises a dielectric 730 and the second material comprises a conductive material 720 (e.g., metal). In some embodiments, the conductive material 720 comprises an oxide layer 820 formed on the surface thereof, and the dielectric material 730 has carbon residue 830 (illustrated as the letter ‘C’ in the Figures) on the surface thereof. After completing the method 800, the substrate 700 is cleaned of both the oxide layer 820 and the carbon residue 830 leaving a clean conductive material 720 and clean dielectric material 730. The order of the method processes can vary with the carbon residue removal occurring before or after the oxide layer removal.

Referring to FIGS. 6 through 8, in one or more embodiments, the method 800 comprises operation 802 in which the carbon residue 830 is removed from the dielectric material 730 on the surface of the substrate 700, followed by operation 804 in which the metal oxides of the oxide layer 820 are reduced, leaving the clean conductive material 720 on the bottom surface 716 of the feature 710 which is part of the substrate surface 711. This order of operations is illustrated on the left side of FIG. 8.

Operation 802, in which the carbon residue 830 on the surface of the dielectric material 730 is removed from the substrate surface 711 is performed by exposing the substrate surface 711 to a microwave plasma. In some embodiments, the microwave plasma is a remote plasma. As used in this manner, the substrate surface 711 refers to the exposed surfaces of both the conductive material 720 and the dielectric material 730. During method 800, the substrate surface 711 is located (or positioned) adjacent to a first side 610a of the permeable barrier 610 and the microwave source assembly 370 is located adjacent to the second side 610b of the permeable barrier 610. The permeable barrier 610 is spaced from both the substrate surface 711 and the microwave source assembly 370. In some embodiments, the permeable barrier 610 is spaced from the substrate surface 711 by an amount in the range of 0.3 inches to 2 inches, or in the range of 0.5 inches to 1.5 inches, or in the range of 0.75 inches to 1.25 inches. In some embodiments, the permeable barrier 610 is spaced from the microwave source assembly 370 by an amount in the range of 0.5 inches to 3 inches, or in the range of 0.75 inches to 2.5 inches, or in the range of 1 inch to 2 inches.

Operation 802 results in a substrate 700 with an oxide layer 820 remaining on the conductive material 720 portion of the substrate surface 711 and substantially no carbon residue 830. As used in this manner, “substantially no carbon residue” means that the amount of carbon is reduced by greater than or equal to 90%, 95%, 98% or 99% from the initial carbon content. In some embodiments, “substantially no carbon residue” means that the carbon signal of a secondary ion mass spectrometry (SIMS) analysis is statistically at or below the noise level (e.g., a signal-to-noise ratio less than or equal to 3, 2.5 or 2).

In some embodiments, operation 802 occurs while the gas inlets are open, allowing a process gas to flow across the substrate surface 711. The gas inlets 589 are located in one or more of the plasma source assembly 370 or the sidewalls 602 of the processing chamber 600. In some embodiments, the process gas flowing across the substrate surface 711 comprises hydrogen radicals. In some embodiments, the process gas flowing across the substrate surface comprises substantially no hydrogen ions. As used in this manner, “substantially no hydrogen ions” means that the amount of hydrogen ions at the substate surface (on the side of the permeable barrier 610 adjacent the substrate surface 711) is less than or equal to 5%, 2%, 1% or 0.5% of the amount of hydrogen radicals at the substrate surface, as measured by an ion analyzer.

During operation 802, the power of the microwave source and the pressure in the process chamber can be tuned to improve process results. In some embodiments, the microwave power is in the range of 2000 W to 5000 W, and the pressure is greater than or equal to 250 mTorr.

At operation 804, the metal oxides (oxide layer 820) at the substrate surface 711 (the surface of the conductive material 720 or the bottom surface 716 of the feature 710) are reduced by exposing the substrate surface 711 to microwave radiation from the microwave source assembly 370 through the permeable barrier 610 without generating a plasma. In some embodiments, reducing the metal oxide refers to removing oxygen from the metal oxide, leading to a pure metal, or zero-valent metal film. Power supplied to the microwave source during operation 704 is insufficient to generate a plasma within the processing chamber adjacent to the source. In some embodiments, the presence of a plasma is monitored visually and/or by Optical Emission Spectroscopy (OES). In some embodiments, the microwave power is in the range of 1600 W to 3000 W with a processing pressure less than or equal to 250 mTorr.

During operation 804, in some embodiments, reducing metal oxides comprises closed gas inlets 589 to create a static gas environment at the substrate surface 711. The interior volume 583 of the processing chamber 600 in some embodiments, is charged with a process gas and then the inlet and outlet valves of the processing chamber 600 are closed to maintain the static environment within the chamber interior. The microwave source assembly 370 can then be powered in a manner that prevents formation of a plasma while still exposing the substrate surface 711 to microwave radiation to remove the oxide layer 820 from the conductive material 720 of the substrate surface 711. In some embodiments, the process gas comprises molecular hydrogen (H₂). In some embodiments, the process gas (also referred to as a forming gas) comprises one or more of molecular hydrogen (H₂) mixed with helium (He) and/or argon (Ar), or carbon monoxide (CO). In some embodiments, the process gas consists essentially of molecular hydrogen (H₂). As used in this manner, the term “consists essentially of” means that the composition of the process gas is greater than or equal to 95%, 98%, 99% or 99.5% of the stated species, on a molar basis. The flow rate of the process gases can be adjusted based on the process conditions, microwave power, pressure, etc., as the skilled artisan will understand. In some embodiments, hydrogen (H₂) is supplied to the process chamber with a flow rate in the range of 50 sccm to 300 sccm. In some embodiments, argon (Ar) is supplied to the process chamber with a flow rate of up to 500 sccm.

In some embodiments, reducing metal oxides at operation 804 removes substantially no carbon from the substrate surface 711. As used in this manner, the term “substantially no carbon” means that less than or equal to 5%, 2% or 1% of the initial carbon content is removed by the plasma-less microwave radiation exposure. In some embodiments, “substantially no carbon” means that the carbon signal of a secondary ion mass spectrometry (SIMS) analysis is statistically at or below the noise level (e.g., a signal-to-noise ratio less than or equal to 3, 2.5 or 2).

In some embodiments, as shown on the left-side path of method 800, removing carbon residue at operation 802 occurs prior to reducing metal oxides at operation 804. In some embodiments, as shown on the right-side path of method 800, reducing metal oxides at operation 804 occurs prior to removing carbon residue at operation 802.

The temperature of the wafer during method 800 can vary depending on, for example, the thermal budget of the device being formed. For example, back-end-of-line (BEOL) processes typically operate at a lower temperature than middle-of-line (MOL) processes. In some embodiments, the method 800 is performed as part of the BEOL manufacturing process and the wafer is maintained at a temperature less than or equal to 350° C. In some embodiments, the method 800 is performed as part of the MOL manufacturing process and the wafer is maintained at a temperature greater than 350° C. for at least one of operation 802 or operation 804. The wafer temperature can be maintained at the same temperature for operation 802 and operation 804, or at different temperatures for each operation.

In some embodiments, reducing metal oxides at operation 804 results in an acceptable amount of damage to a low-k dielectric on the substrate surface. As used in this manner, an “acceptable amount of damage” means that less than or equal to 5%, 2% or 1% of the surface area of the low-k dielectric is affected. In some embodiments, the low-k dielectric surface is monitored by one or more of surface x-ray photoelectron spectroscopy (XPS), depth profile XPS, FTIR analysis, Hg probe analysis.

In some embodiments, the method 800 further comprises repeating removing the carbon residue at operation 802 and reducing the metal oxides at operation 804 in an alternating manner. For example, short duration operation 802 and operation 804 may be used to clean the substrate surface to minimize any unwanted side effects or damage to either of the surface materials.

In some embodiments, the method 800 is part of a gap fill process. For example, after completing operation 802 and operation 804, one or more subsequent operations, such as, for example, filling the gap of the feature 710 with a conductive material, to form an interconnect, and that the one or more subsequent operations can be performed without undue experimentation.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A semiconductor manufacturing processing methods comprising:
removing carbon residue from a substrate surface by exposing the substrate surface located adjacent to a first side of a permeable barrier to a microwave plasma generated by a microwave source located adjacent to a second side of the permeable barrier; and
reducing metal oxides from a substrate surface by exposing the substrate surface to microwave radiation from the microwave source through the permeable barrier without generating a plasma.

2. The method of claim 1, wherein removing carbon residue occurs prior to reducing metal oxides.

3. The method of claim 1, wherein reducing metal oxides occurs prior to removing carbon residue.

4. The method of claim 1, wherein removing carbon residue comprises open gas inlets to allow a process gas to flow across the substrate surface.

5. The method of claim 4, wherein the process gas comprises hydrogen radicals.

6. The method of claim 1, wherein reducing metal oxides comprises closed gas inlets to create a static gas environment at the substrate surface.

7. The method of claim 6, wherein the substrate surface is exposed to a process gas with the microwave radiation.

8. The method of claim 7, wherein the process gas comprises molecular hydrogen.

9. The method of claim 6, wherein reducing metal oxides removes substantially no carbon from the substrate surface.

10. The method of claim 1, wherein the permeable barrier comprises a plurality of plates with openings therethrough.

11. The method of claim 10, wherein the permeable barrier comprises one or more of quartz, ceramic or metal.

12. The method of claim 10, wherein the openings through the plurality of plates are staggered slits configured so that openings in one plate are not aligned with openings in an adjacent plate.

13. The method of claim 10, wherein the permeable barrier filters ions from the microwave plasma while removing carbon residue from the substrate surface.

14. The method of claim 1, wherein the substrate surface comprises a metal surface and a low-k dielectric surface.

15. The method of claim 14, wherein reducing metal oxides results in an acceptable amount of damage to a low-k dielectric on the substrate surface.

16. The method of claim 1, wherein removing the carbon residue and reducing the metal oxides are repeated in an alternating manner.

17. A semiconductor manufacturing processing methods comprising:
removing carbon residue from a substrate surface comprising a metal surface and a low-k dielectric surface by exposing the substrate surface located adjacent to a first side of a permeable barrier to hydrogen radicals from a microwave plasma generated by a microwave source, the microwave plasma generated on a second side of the permeable barrier; and
reducing metal oxides from a substrate surface by exposing the substrate surface to microwave radiation from the microwave source through the permeable barrier without generating a plasma.

18. The method of claim 17, wherein reducing metal oxides comprises a static gas environment comprising molecular hydrogen at the substrate surface.

19. The method of claim 17, wherein the permeable barrier comprises a plurality of plates with openings therethrough.

20. The method of claim 17, wherein the permeable barrier comprises one or more of quartz, ceramic or metal.
